(19) United States
(12) Patent Application Publication
(10) Pub. No.: US 2024/0405001 A1
(43) Pub. Date: Dec. 5, 2024

(54) DISPLAY DEVICE AND METHOD OF MANUFACTURING THE SAME

(71) Applicant: Japan Display Inc., Tokyo (JP)

(72) Inventors: Kenichi TAKEMASA, Tokyo (JP); Kazuyuki YAMADA, Tokyo (JP); Keisuke ASADA, Tokyo (JP); Daiki ISONO, Tokyo (JP)

(21) Appl. No.: 18/655,479

(22) Filed: May 6, 2024

(30) Foreign Application Priority Data
May 29, 2023 (JP) 2023-088003

(51) Int. Cl. H01L 25/075; H01L 33/20; H01L 33/38

(52) U.S. Cl. CPC H01L 25/0753; H01L 33/20; H01L 33/382; H01L 2933/0016

(57) ABSTRACT

A display device includes a first substrate having a first surface and a plurality of LED elements mounted on the first surface of the first substrate. Each of the plurality of LED elements includes a main body portion having a second surface facing the first surface of the first substrate and a third surface on a side opposite to the second surface, an anode electrode and a cathode electrode provided on the second surface of the main body portion, and an organic film bonded to the third surface of the main body portion. The organic film has a fourth surface facing and bonded to the third surface and a fifth surface on a side opposite to the fourth surface. The fifth surface of the organic film has a plurality of depressions.

### CROSS REFERENCES TO RELATED APPLICATIONS

The present application claims priority to Japanese Patent Application No. 2023-088003 filed on May 29, 2023, the disclosure of which is incorporated herein by reference.

### TECHNICAL FIELD

The present invention relates to a display device.

### BACKGROUND

Patent Document 1 (Japanese Unexamined Patent Application Publication No. 2020-167251) discloses a method of manufacturing a micro LED display device using a transfer substrate.

### SUMMARY

There is a micro LED display device using a plurality of LED elements (inorganic light emitting elements) as light emitting elements. The inventors of this application have been studying a technique for improving the performance of a display device using a plurality of LED elements like the micro LED display device.

An object of the present invention is to provide a technique capable of improving the performance of a display device.

A display device according to an embodiment includes: a first substrate having a first surface; and a plurality of inorganic light emitting diode elements mounted on the first surface of the first substrate. Each of the plurality of inorganic light emitting diode elements includes: a main body portion having a second surface facing the first surface of the first substrate and a third surface on a side opposite to the second surface; a first electrode and a second electrode provided on the second surface of the main body portion; and a first organic film bonded to the third surface of the main body portion. The first organic film has a fourth surface bonded to the third surface and a fifth surface on a side opposite to the fourth surface. The fifth surface of the first organic film has a plurality of depressions.

A method of manufacturing a display device according to another embodiment includes steps of: (a) preparing a first substrate having a first surface; (b) preparing a plurality of inorganic light emitting diode elements; and (c) mounting the plurality of inorganic light emitting diode elements on the first surface of the first substrate. The step (b) includes steps of: (b1) forming a main body portion, a first electrode, and a second electrode of each of the plurality of inorganic light emitting diode elements on an element forming substrate; (b2) transferring the plurality of main body portions formed on the element forming substrate to a first transfer substrate; (b3) bonding the plurality of main body portions and a plurality of first organic films held on an organic film holding substrate, respectively; and (b4) peeling off a bonding interface between the organic film holding substrate and the plurality of first organic films. The main body portion has a second surface facing the first surface of the first substrate in the step (c) and a third surface on a side opposite to the second surface. Each of the first electrode and the second electrode is formed on the second surface of the main body portion in the step (b1). The first organic film has a fourth surface bonded to the third surface in the step (b3) and a fifth surface on a side opposite to the fourth surface. The fifth surface of the first organic film has a plurality of depressions.

### BRIEF DESCRIPTION OF DRAWINGS

FIG. 1 is a plan view showing a configuration example of a micro LED display device according to an embodiment;

FIG. 2 is a circuit diagram showing a configuration example of a circuit around a pixel shown in FIG. 1;

FIG. 3 is a transparent enlarged plan view showing an example of a peripheral structure of an LED element arranged in each of the plurality of pixels of the display device shown in FIG. 1;

FIG. 4 is an enlarged cross-sectional view taken along the line A-A in FIG. 3;

FIG. 5 is an enlarged cross-sectional view of the LED element shown in FIG. 4;

FIG. 6 is an enlarged perspective view showing an example of a shape of one surface of an organic film shown in FIG. 5;

FIG. 7 is an explanatory diagram schematically showing a traveling direction of light generated by the LED element shown in FIG. 5;

FIG. 8 is an explanatory diagram showing an example of a process flow of a method of manufacturing a display device;

FIG. 9 is a cross-sectional view showing an LED forming step shown in FIG. 8;

FIG. 10 is a cross-sectional view showing a main body portion picking step shown in FIG. 8;

FIG. 11 is a cross-sectional view showing an organic film bonding step shown in FIG. 8;

FIG. 12 is a cross-sectional view showing an organic film holding substrate separating step shown in FIG. 8;

FIG. 13 is a cross-sectional view showing an LED element holding step shown in FIG. 8; and

FIG. 14 is a cross-sectional view showing an LED element transferring step shown in FIG. 8.

### DETAILED DESCRIPTION OF THE INVENTION

Hereinafter, each embodiment of the present invention will be described with reference to drawings. Note that the disclosure is merely an example, and it is a matter of course that any alteration that is easily made by a person skilled in the art while keeping a gist of the present invention is included in the range of the present invention. In addition, the drawings schematically illustrate a width, a thickness, a shape, and the like of each portion as compared with actual aspects in order to make the description clearer, but the drawings are merely examples and do not limit the interpretation of the present invention. Further, the same elements as those described in relation to the foregoing drawings are denoted by the same or related reference characters in this specification and the respective drawings, and detailed descriptions thereof will be omitted as appropriate.

### <Display Device>

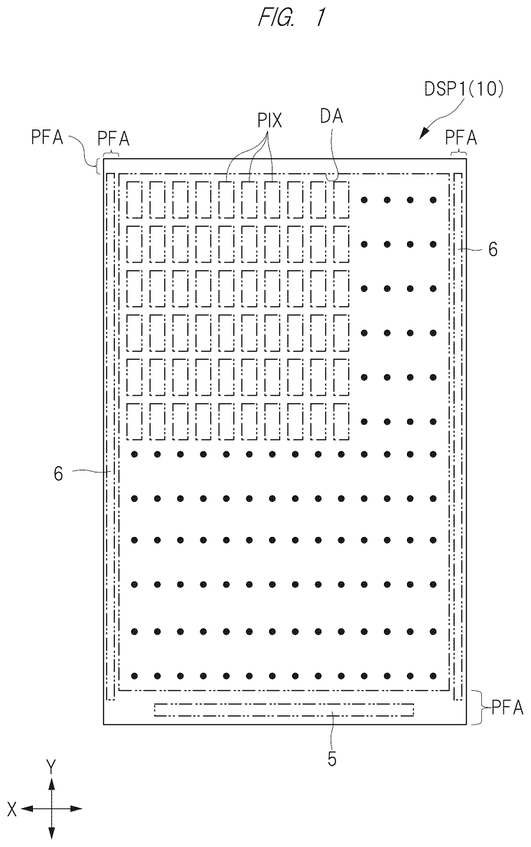

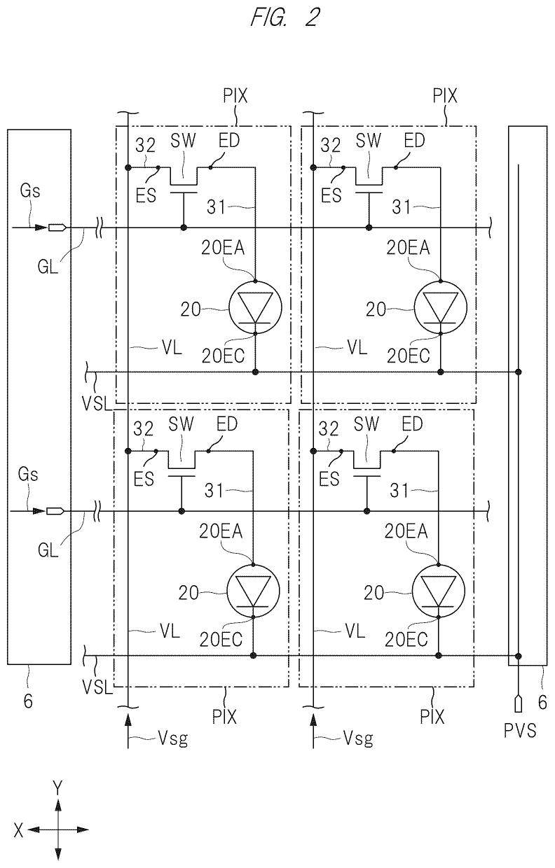

First, a configuration example of a micro LED display device, which is a display device of this embodiment, will be described. FIG. 1 is a plan view showing a configuration example of a micro LED display device according to an embodiment. In FIG. 1, the boundary between a display region DA and a peripheral region PFA, a control circuit 5, a drive circuit 6, and each of a plurality of pixels PIX are indicated by double-dot dashed lines. FIG. 2 is a circuit diagram showing a configuration example of a circuit around the pixel shown in FIG. 1.

FIG. 1 illustrates the X direction and the Y direction. The X direction and the Y direction intersect with each other. In the example described below, the X direction is orthogonal to the Y direction. In the following, an X-Y plane including the X direction and the Y direction will be described as a plane parallel to a display surface of the display device. In the following description, “in plan view” means the case where a plane parallel to the X-Y plane is viewed, unless it is explicitly stated that it should be interpreted in different meaning. Furthermore, as will be described later, the normal direction with respect to the X-Y plane will be referred to as the “Z direction” or the thickness direction. The X direction, the Y direction, and the Z direction are directions that intersect with each other, and more specifically, are directions that are orthogonal to each other.

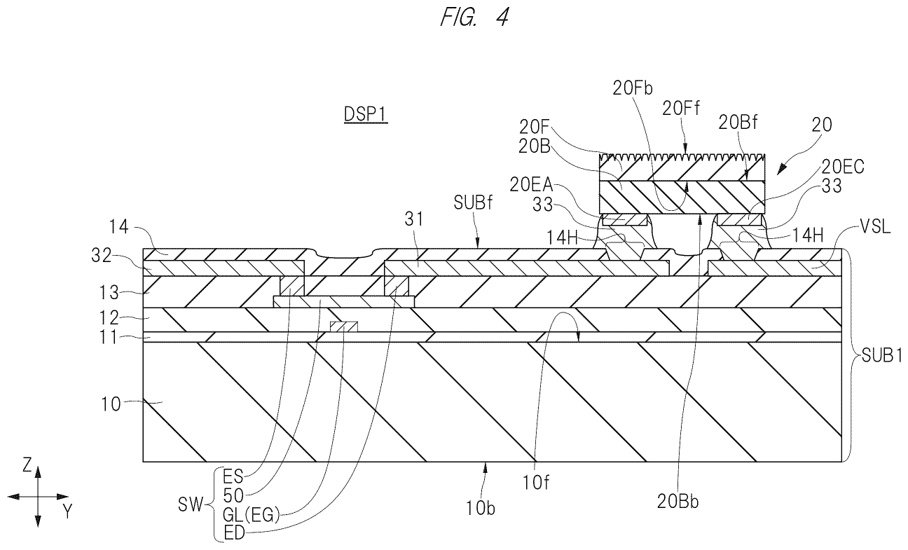

As shown in FIG. 1, a display device DSP1 of this embodiment includes the display region DA, the peripheral region PFA surrounding the display region DA in a frame shape, and the plurality of pixels PIX arranged in a matrix in the display region DA. Further, the display device DSP1 includes a substrate 10, the control circuit 5 formed on the substrate 10, and the drive circuit 6 formed on the substrate 10. The substrate 10 is made of glass or a resin. As shown in FIG. 4, the substrate 10 has a surface 10f and a surface 10b on a side opposite to the surface 10f.

The control circuit 5 is a control circuit configured to control the driving of a display function of the display device DSP1. For example, the control circuit 5 is a driver IC (Integrated Circuit) mounted on the substrate 10. In the example shown in FIG. 1, the control circuit 5 is arranged along one short side of the four sides of the substrate 10. Furthermore, in an example of this embodiment, the control circuit 5 includes a signal line drive circuit configured to drive a wiring (video signal wiring) VL (see FIG. 2) connected to the plurality of pixels PIX. However, the position and configuration example of the control circuit 5 are not limited to those in the example shown in FIG. 1, and there are various modifications. For example, in FIG. 1, a circuit board such as a flexible board may be connected to the position shown as the control circuit 5, and the above-described driver IC may be mounted on the circuit board. Further, for example, the signal line drive circuit configured to drive the wiring VL may be formed separately from the control circuit 5.

The drive circuit 6 includes a circuit configured to drive scan signal lines GL (see FIG. 2 described later) in the plurality of pixels PIX. Also, the drive circuit 6 includes a circuit configured to supply a reference potential to the LED element mounted in each of the plurality of pixels PIX. The drive circuit 6 drives the plurality of scan signal lines GL based on control signals from the control circuit 5. In the example shown in FIG. 1, the drive circuit 6 is arranged along each of two long sides of the four sides of the substrate 10. However, the position and configuration example of the drive circuit 6 are not limited to those in the example shown in FIG. 1, and there are various modifications. For example, in FIG. 1, a circuit board such as a flexible board may be connected to the position shown as the control circuit 5, and the above-described drive circuit 6 may be mounted on the circuit board.

Next, a circuit configuration example of the pixel PIX will be described with reference to FIG. 2. Note that FIG. 2 illustrates four pixels PIX representatively, but each of the plurality of pixels PIX shown in FIG. 1 includes the circuit similar to the pixel PIX shown in FIG. 2. In the following description, the circuit including the switch and an LED element 20 in the pixel PIX may be referred to as a pixel circuit. The pixel circuit is a voltage signal circuit configured to control the light emission state of the LED element 20 according to a video signal Vsg supplied from the control circuit 5 (see FIG. 1).

As shown in FIG. 2, the pixel PIX includes the LED element 20. The LED element 20 is a micro light emitting diode mentioned above. The LED element 20 has an anode electrode 20EA and a cathode electrode 20EC. The cathode electrode 20EC of the LED element 20 is connected to a wiring VSL to which a reference voltage (fixed potential) PVS is supplied. The anode electrode 20EA of the LED element 20 is electrically connected to a drain electrode ED of a switching element SW via a wiring 31.

The pixel PIX includes the switching element SW. The switching element SW is a transistor configured to control a connection state (on or off state) between the pixel circuit and the wiring VL in response to a control signal Gs. The switching element SW is, for example, a thin film transistor. When the switching element SW is in the on state, the video signal Vsg is input to the pixel circuit from the wiring VL.

The drive circuit 6 includes a shift register circuit, an output buffer circuit, and others (not shown). The drive circuit 6 outputs pulses based on a horizontal scanning start pulse transmitted from the control circuit 5 (see FIG. 1), and outputs the control signal Gs.

Each of the plurality of scan signal lines GL extends in the X direction. The scan signal line GL is connected to a gate electrode of the switching element SW. When the control signal Gs is supplied to the scan signal line GL, the switching element SW is turned on and the video signal Vsg is supplied to the LED element 20.

### <Peripheral Structure of LED Element>

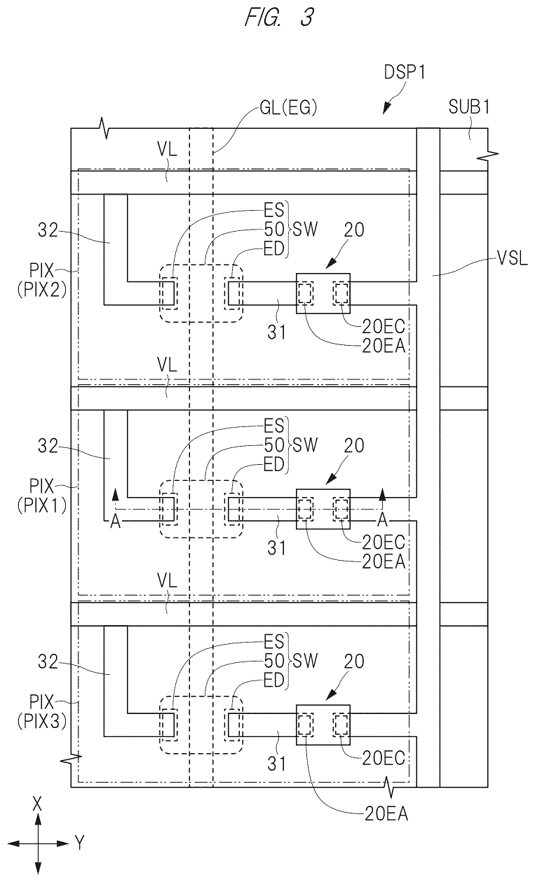

Next, the peripheral structure of the LED element arranged in each of the plurality of pixels PIX shown in FIG. 1 will be described. FIG. 3 is a transparent enlarged plan view showing an example of a peripheral structure of an LED element arranged in each of the plurality of pixels of the display device shown in FIG. 1. In FIG. 3, the illustration of an inorganic insulating layer 14 shown in FIG. 4 is omitted. In FIG. 3, outlines of semiconductor layers, electrodes, and scan signal lines are indicated by dotted lines. FIG. 4 is an enlarged cross-sectional view taken along the line A-A in FIG. 3.

As shown in FIG. 3, the display device DSP1 has the plurality of pixels PIX including a pixel PIX1 (pixel PIX1, pixel PIX2, and pixel PIX3 in the example shown in FIG. 3). Each of the plurality of pixels PIX has the switching element SW, the LED element (light emitting element) 20, the wiring 31, and a wiring 32.

Note that, in each of the pixels PIX1, PIX2, and PIX3, for example, the LED element 20 configured to emit visible light of one color of red, green, and blue is mounted, and the switching element SW configured to drive the LED element 20 is formed. The color display is possible by controlling the output and timing of the visible light emitted from the LED elements 20 provided in the pixels PIX1, PIX2, and PIX3. When a plurality of pixels PIX configured to emit visible light of different colors are combined in this way, the pixel PIX for each color is sometimes referred to as a sub-pixel, and the set of the plurality of pixels PIX is sometimes referred to as a pixel. In this embodiment, the part corresponding to the sub-pixel mentioned above is referred to as a pixel PIX.

The wiring 31 is electrically connected to the drain electrode ED of the switching element SW and the anode electrode 20EA of the LED element 20. The wiring 32 is connected to a source electrode ES of the switching element SW. In the example shown in FIG. 3, the wiring 32 has a bent structure, and one end thereof is connected to the source electrode ES of the switching element SW and the other end thereof is connected to the wiring VL. The scan signal line GL is used as the gate electrode EG of the switching element SW.

The display device DSP1 further includes the wiring VL extending along the Y direction across the plurality of pixels PIX (see FIG. 2) and electrically connected to the wiring 32 and the wiring VSL extending along the X direction intersecting the Y direction (orthogonally in FIG. 3) across the plurality of pixels PIX and electrically connected to the cathode electrode 20EC of the LED element 20. Note that the layout shown in FIG. 3 is an example, and there are various modifications. For example, as a modification of FIG. 3, the structure in which the switching element SW has a gate electrode (not shown) and the gate electrode is connected to the scan signal line GL is also possible. In this modification, the scan signal line GL may be arranged at a position that does not overlap a semiconductor layer 50.

As shown in FIG. 4, the display device DSP1 is an electronic device that includes the substrate 10 made of glass or a resin and a plurality of insulating layers stacked on the substrate 10. The plurality of insulating layers provided in the display device DSP1 include an inorganic insulating layer 11, an inorganic insulating layer 12, an inorganic insulating layer 13, and an inorganic insulating layer 14 stacked on the substrate 10. The substrate 10 has the surface 10f and the surface 10b on the side opposite to the surface 10f. Each of the inorganic insulating layers 11, 12, 13, and 14 is stacked on the surface 10f of the substrate 10.

The switching element SW includes the inorganic insulating layer 12 formed on the substrate 10, the semiconductor layer 50 formed on the inorganic insulating layer 12, the drain electrode ED connected to a drain region of the semiconductor layer 50, the source electrode ES connected to a source region of the semiconductor layer 50, and the inorganic insulating layer 13 covering the semiconductor layer 50. Each of the wiring 31 and the wiring 32 is a stacked film of, for example, a conductor layer made of titanium or a titanium alloy and a conductor layer made of aluminum or an aluminum alloy. A stacked film in which an aluminum layer is sandwiched between titanium layers is referred to as a TAT stacked film.

The example shown in FIG. 4 is an example of the bottom gate type in which the gate electrode EG is located between the semiconductor layer 50 and the substrate 10. In the case of the bottom gate type, a part of the inorganic insulating layer 12 located between the gate electrode EG and the semiconductor layer 50 functions as a gate insulating layer. In addition, the inorganic insulating layer 12 also functions as a base layer for forming the semiconductor layer 50. Note that the position of the gate electrode EG is not limited to that in the example shown in FIG. 4, and a top gate type described later as a modification is also possible.

The material constituting each of the inorganic insulating layers 11, 12, 13, and 14 is not particularly limited. For example, silicon oxide (SiO₂) and silicon nitride (SiN) can be used. Further, the semiconductor layer 50 is a semiconductor film made of a silicon film doped with an impurity of P or N conductivity type.

Each of the source electrode ES and the drain electrode ED is a contact plug for making electrical contact with either the source region or the drain region of the semiconductor layer 50. The material of the contact plug is, for example, tungsten. As a modification of FIG. 4, contact holes may be formed in the inorganic insulating layer 13 so as to expose the source region and the drain region of the semiconductor layer 50, and a part of the wiring 31 and a part of the wiring 32 may be buried in the contact holes, respectively. In this case, the parts of the wiring 31 and the wiring 32 buried in the contact holes are in contact with the semiconductor layer 50, and the contact interfaces between the wirings 31 and 32 and the semiconductor layer 50 can be regarded as the drain electrode ED and the source electrode ES.

A stacked body of the substrate 10 and a plurality of insulating layers (inorganic insulating layers 11, 12, 13, and 14 in the example shown in FIG. 4) stacked on the substrate 10 is defined as a substrate SUB1. The substrate SUB1 has a surface SUBf.

Furthermore, the display device DSP1 includes a plurality of bump electrodes 33. The bump electrode 33 is a terminal for mounting the LED element 20 on the substrate 10. Therefore, one of the two bump electrodes 33 is connected to the anode electrode 20EA of the LED element 20, and the other is connected to the cathode electrode 20EC of the LED element 20.

The bump electrode 33 is connected to the wiring 31 at a position overlapping an opening 14H formed in the inorganic insulating layer 14, and protrudes from the inorganic insulating layer 14. Further, the bump electrode 33 is made of, for example, solder containing tin. Alternatively, the bump electrode 33 may be a stacked body of a metal layer made of a metal material having a higher electrical conductivity than solder such as copper and a solder layer.

### <LED Element>

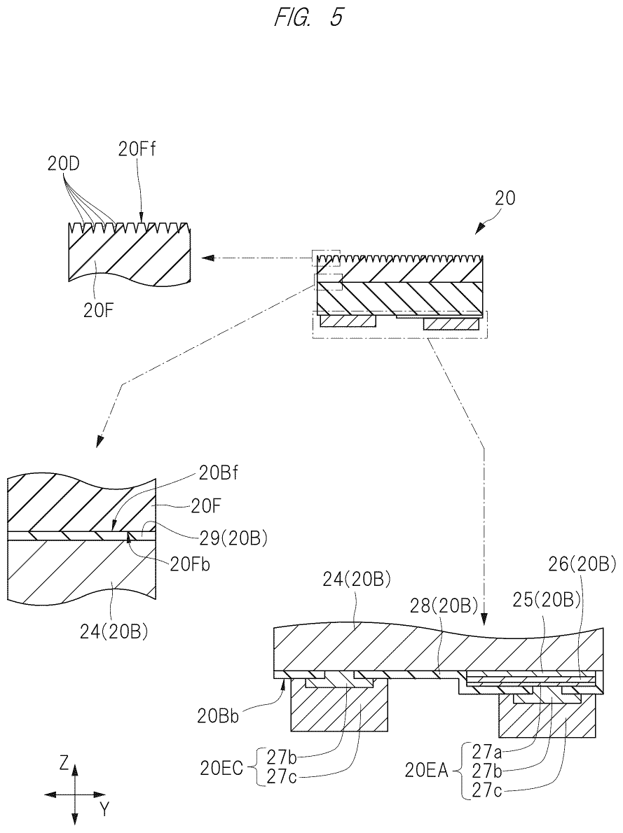

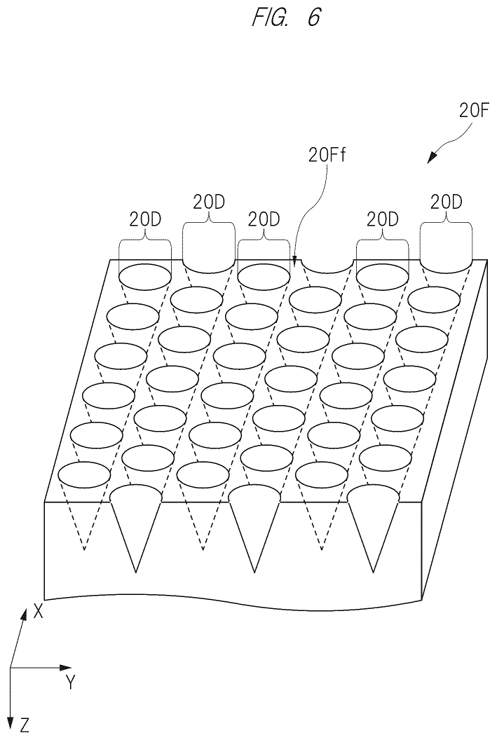

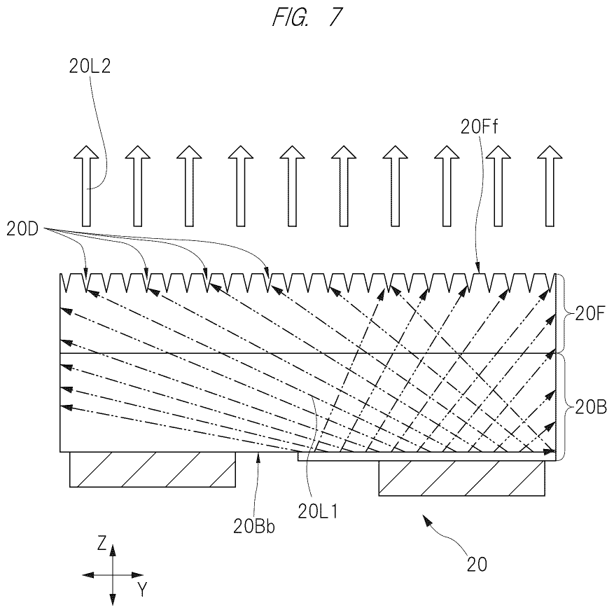

Next, the LED element 20 shown in FIG. 3 and FIG. 4 will be described. FIG. 5 is an enlarged cross-sectional view of the LED element shown in FIG. 4. FIG. 6 is an enlarged perspective view showing an example of a shape of one surface of an organic film shown in FIG. 5. FIG. 7 is an explanatory diagram schematically showing a traveling direction of light generated by the LED element shown in FIG. 5.

As shown in FIG. 4, each of the plurality of LED elements 20 shown in FIG. 3 has a main body portion 20B, a transparent (in other words, visible light transmitting) organic film 20F, the anode electrode 20EA, and the cathode electrode 20EC.

The main body portion 20B of the LED element 20 has a surface 20Bb facing the surface SUBf of the substrate SUB1 and a surface 20Bf on the side opposite to the surface 20Bb. Each of the anode electrode 20EA and the cathode electrode 20EC is provided on the surface 20Bb of the main body portion 20B. The organic film 20F is bonded to the surface 20Bf of the main body portion 20B. The organic film 20F has a surface 20Fb that faces the surface 20Bf and is bonded to the surface 20Bf and a surface 20Ff on the side opposite to the surface 20Fb.

For example, the detailed structure of the LED element 20 is illustrated in FIG. 5. In the example shown in FIG. 5, the main body portion 20B of the LED element 20 includes an N-type semiconductor layer 24, an active layer 25 stacked on the N-type semiconductor layer 24, a P-type semiconductor layer 26 stacked on the active layer 25, and a passivation film 28 which is an inorganic insulating film.

The N-type semiconductor layer 24 is formed as a common base layer for the anode electrode 20EA and the cathode electrode 20EC, and the active layer 25 and the P-type semiconductor layer 26 are stacked on a side of the anode electrode 20EA. On the side of the anode electrode 20EA, a transparent electrode layer 27a is formed on the P-type semiconductor layer 26. The transparent electrode layer 27a on the side of the anode electrode 20EA and the N-type semiconductor layer 24 on the side of the cathode electrode 20EC are covered with the passivation film 28 which is an inorganic insulating film.

In the passivation film 28, openings are formed at locations where the anode electrode 20EA and the cathode electrode 20EC are to be formed. In each opening, a metal electrode layer 27c is stacked via a seed layer 27b. The anode electrode 20EA is a stacked body of the transparent electrode layer 27a, the seed layer 27b, and the metal electrode layer 27c. Meanwhile, the cathode electrode 20EC is a stacked body of the seed layer 27b and the metal electrode layer 27c stacked on the N-type semiconductor layer 24. A buffer layer 29 made of, for example, gallium nitride is formed between the N-type semiconductor layer 24 and a substrate SS1.

Note that FIG. 5 illustrates an example in which the buffer layer 29 remains between the organic film 20F and the N-type semiconductor layer 24. However, in the manufacturing process of the LED element 20, the buffer layer 29 is modified and removed by laser irradiation in some cases. In this case, the buffer layer 29 does not remain between the organic film 20F and the N-type semiconductor layer 24, and the surface 20Fb of the organic film 20F may be bonded to the N-type semiconductor layer 24.

Further, as shown in FIG. 5 and FIG. 6, the surface 20Ff of the organic film 20F has a plurality of depressions 20D. In the example shown in FIG. 6, the plurality of depressions 20D are arranged in a grid pattern. Specifically, the plurality of depressions 20D are arranged in a houndstooth pattern.

As shown in FIG. 7, the depressions 20D of the organic film 20F function as an optical element that increases the component of emission light 20L2 traveling in the Z direction corresponding to the thickness direction of the LED element 20 by refracting a part of light 20L1 emitted from the light emitting layer of the LED element 20. The Z direction coincides with the normal direction of the surface 20Bb of the main body portion 20B of the LED element 20.

If the component of the emission light 20L2 traveling in the Z direction of the light emitted from the LED element 20 can be increased as in this embodiment, it is possible to increase the amount of light that can be used as display light. As a result, the brightness of the display device can be improved. In other words, the power required to obtain the desired brightness can be reduced.

As shown in FIG. 6, each of the plurality of depressions 20D has a conical shape. The shape of the depression 20D is not limited to the conical shape as long as it is possible to exert the function as an optical element that increases the component of the emission light 20L2 traveling in the Z direction by refracting a part of the light 20L1 as shown in FIG. 7, and various modifications can be applied. However, according to studies by the inventors of this application, it is particularly preferable that the shape of the depression 20D is a conical shape.

The organic film 20F is easier to process than inorganic films such as metal films and metal oxide films. Therefore, the shape of the plurality of depressions 20D formed in the organic film 20F (for example, the height of the cone, the radius of the bottom surface, the inclination angle of the side surfaces, and others shown in FIG. 6) can be easily processed into an optimal shape in consideration of the refraction characteristics.

In the example of this embodiment, the organic film 20F is made of a polyimide resin. The refractive index of the polyimide resin for visible light can be easily adjusted to a value close to the refractive index of the main body portion 20B of the LED element 20 for visible light. For example, in the case of this embodiment, the refractive index of the organic film 20F made of a polyimide resin is higher than the refractive index of air and is lower than the refractive index of a gallium nitride film (for example, the buffer layer 29 shown in FIG. 5). More specifically, the difference in refractive index between the organic film 20F and the gallium nitride film is smaller than the difference in refractive index between the organic film 20F and air. Therefore, it is preferable that the organic film 20F is made of a polyimide resin for optical reasons. Further, from the viewpoint of ease of processing, it is particularly preferable that the organic film 20F is made of a polyimide resin.

Incidentally, in the case of the example shown in FIG. 5, the surface 20Bf of the main body portion 20B is not subjected to surface roughening treatment. Therefore, the flatness of the surface 20Ff of the organic film 20F is lower than the flatness of the surface 20Bf. However, from the viewpoint of improving the bonding strength between the surface 20Fb of the organic film 20F and the surface 20Bf of the main body portion 20B, the surface 20Bf of the main body portion 20B is subjected to surface roughening treatment in some cases. Even in this case, it is preferable that the flatness of the surface 20Ff of the organic film 20F is equal to or lower than the flatness of the surface 20Bf of the main body portion 20B.

As described above, the organic film 20F functions as an optical element. Therefore, from the viewpoint of improving the brightness of the display device DSP1 (see FIG. 4), it is preferable that most of the light 20L1 shown in FIG. 7 passes through the surface 20Ff of the organic film 20F. In the case of this embodiment, the area of the surface 20Fb of the organic film 20F is equal to or larger than the area of the surface 20Bf. Further, the entire surface 20Bf of the main body portion 20B is bonded to the surface 20Fb of the organic film 20F. In this way, it is possible to maximize the amount of light 20L1 emitted from the surface 20Ff via the main body portion 20B and the organic film 20F in this order.

However, if the area of the surface 20Fb of the organic film 20F is larger than the area of the surface 20Bf, a part of the organic film 20F protrudes from the main body portion 20B in the direction along the X-Y plane shown in FIG. 3. If the volume of the protruding part increases, for example, the bonding interface between the surface 20Fb and the surface 20Bf may be peeled off when an external force is applied to the organic film 20F during the manufacturing process. From the viewpoint of suppressing the peeling of the bonding interface between the surface 20Fb and the surface 20Bf, it is preferable that the area of the surface 20Fb of the organic film 20F and the area of the surface 20Bf of the main body portion 20B are approximately equal to each other.

In the case of this embodiment, the area of the surface 20Fb of the organic film 20F and the area of the surface 20Bf of the main body portion 20B are equal to each other. In this case, almost all of the surface 20Bf of the main body portion 20B is bonded to the surface 20Fb of the organic film 20F. Also, even if the positions of the surface 20Fb and the surface 20Bf do not completely match due to positional accuracy in the manufacturing process, the volume of the part of the organic film 20F that protrudes from the main body portion 20B can be made so small as to be practically negligible.

### <Method of Manufacturing Display Device>

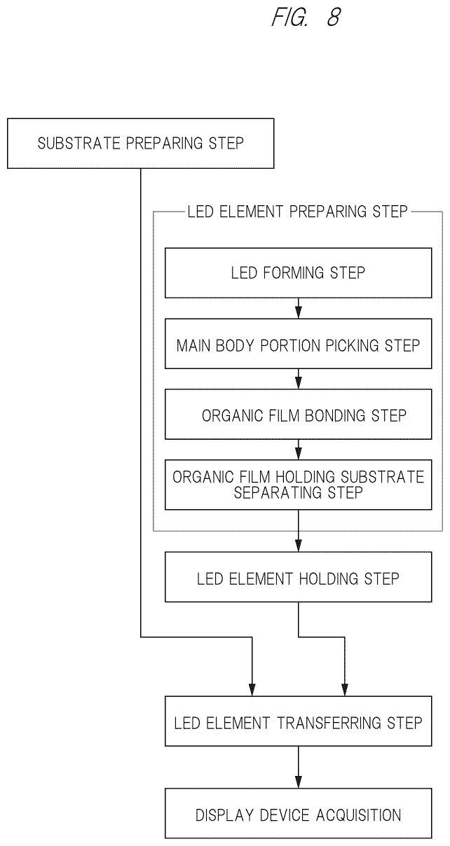

A method of manufacturing a display device according to this embodiment will be described based on a method of manufacturing the display device DSP1 shown in FIG. 3 as a representative example. FIG. 8 is an explanatory diagram showing an example of a process flow of a method of manufacturing a display device.

As shown in FIG. 8, the method of manufacturing the display device according to this embodiment includes a substrate preparing step, an LED element preparing step, an LED element holding step, and an LED element transferring step. The LED element preparing step includes an LED forming step, a main body portion picking step, an organic film bonding step, and an organic film holding substrate separating step. Each step shown in FIG. 8 will be described below.

In the substrate preparing step shown in FIG. 8, the substrate SUB1 shown in FIG. 4 is prepared. Since the structure of the substrate SUB1 has already been described above, the repetitive description thereof will be omitted. The substrate SUB1 prepared in this step is in the state before the LED element 20 is mounted shown in FIG. 4. Therefore, the bump electrodes 33 protrude on the surface SUBf of the substrate SUB1.

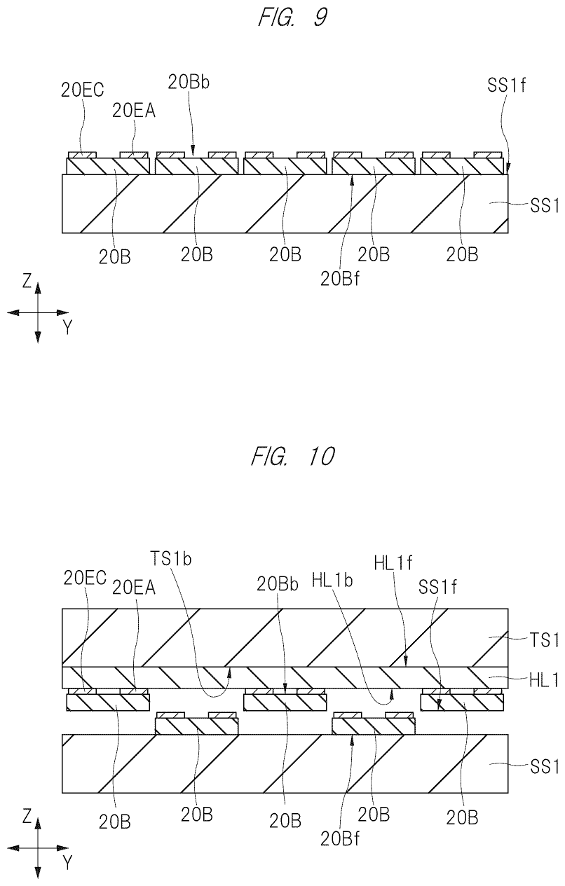

In the LED forming step included in the LED element preparing step shown in FIG. 8, the main body portion 20B, the anode electrode 20EA, and the cathode electrode 20EC of the LED element 20 described with reference to FIG. 5 are formed on a surface SS1f of the substrate SS1 as shown in FIG. 9. The substrate SS1 is an element forming substrate for forming the LED element, and is, for example, a sapphire substrate made of sapphire. FIG. 9 is a cross-sectional view showing the LED forming step shown in FIG. 8.

The main body portion 20 has the surface 20Bf facing the surface SS1f of the substrate SS1 and the surface 20Bb on the side opposite to the surface 20Bf. Each of the anode electrode 20EA and the cathode electrode 20EC is formed on the surface 20Bb.

In this step, the buffer layer 29, the N-type semiconductor layer 24, the active layer 25, the P-type semiconductor layer 26, the transparent electrode layer 27a, and the passivation film 28 described with reference to FIG. 5 are sequentially stacked. Openings are formed in the passivation film 28, and the seed layer 27b and the metal electrode layer 27c are formed on the opening.

In addition, in this step, a plurality of main body portions 20B are collectively formed on one substrate SS1. After the anode electrode 20EA and the cathode electrode 20EC are formed, the stacked film on the substrate SS1 is diced into a plurality of pieces (referred to as a dicing step or a singulation step). Since the plurality of main body portions 20B can be formed at once in the manufacturing method described above, the manufacturing efficiency can be improved.

Next, in the main body portion picking step included in the LED element preparing step shown in FIG. 8, a part or all of the plurality of main body portions 20B are transferred to a transfer substrate TS1 as shown in FIG. 10. FIG. 10 is a cross-sectional view showing the main body portion picking step shown in FIG. 8. The example in FIG. 10 shows the state where a part of (three) main body portions 20B of five main body portions 20B are transferred.

The reasons why a part of the plurality of main body portions 20B are transferred in this way are, for example, as follows. The first reason is that the arrangement pitch of the plurality of main body portions 20B formed on the substrate SS1 is different from the arrangement pitch of the plurality of LED elements 20 mounted on the substrate SUB1 shown in FIG. 3.

The second reason is as follows. That is, a plurality of types of LED elements 20, for example, the LED elements 20 for blue, red, and green are mounted in the display device DSP1. On the other hand, it is preferable that each of the plurality of main body portions 20B collectively formed on the substrate SS1 is of the same type. Therefore, in order to mount different types of LED elements 20 adjacent to each other, it is preferable to pick up a part of the plurality of main body portions 20B in this step.

However, the number of main body portions 20B transferred to the transfer substrate TS1 in this step is not limited to the number shown in FIG. 10, and there are various modifications. For example, as a modification of this embodiment, all of the plurality of main body portions 20B may be picked up in this step.

In this step, it is possible to use the laser lift-up method in which the buffer layer 29 shown in FIG. 5 is modified by irradiating it with a laser and the modified buffer layer is selectively picked up.

The transfer substrate TS1 shown in FIG. 10 is, for example, a glass substrate made of glass. The transfer substrate TS1 has a surface TS1b. A holding layer HL1 is formed on the surface TS1b of the transfer substrate TS1. The holding layer HL1 is made of, for example, an elastically deformable organic film, and is formed so as to cover the entire surface TS1b of the transfer substrate TS1. The holding layer HL1 has a surface HL1f facing the surface TS1b of the transfer substrate TS1 and a surface HL1b on the side opposite to the surface HL1f. At least the surface HL1b or the entire holding layer HL1 is made of an adhesive material, and is capable of adhesively holding the main body portion 20B.

In this step, the buffer layer 29 (see FIG. 5) of a part or all of the plurality of main body portions 20B is modified by irradiating it with a laser in the state where the surface HL1b of the holding layer HL1 is pressed to the anode electrode 20EA and the cathode electrode 20EC formed on the main body portion 20B. Thereafter, by separating the transfer substrate TS1 and the substrate SS1, the main body portions 20B can be transferred to the transfer substrate TS1 as shown in FIG. 10.

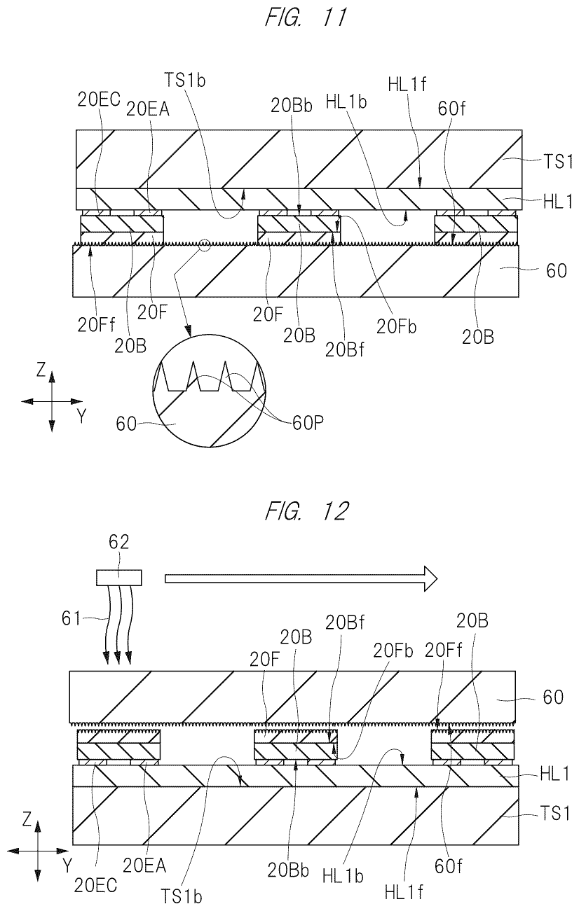

Next, in the organic film bonding step included in the LED element preparing step shown in FIG. 8, the surface 20Fb of the organic film 20F is bonded to each surface 20Bf of the plurality of main body portions 20B as shown in FIG. 11. FIG. 11 is a cross-sectional view showing the organic film bonding step shown in FIG. 8.

An organic film holding substrate 60 prepared in this step has a surface 60f and a plurality of organic films 20F formed on the surface 60f. The plurality of organic films 20F are spaced apart from each other. Furthermore, a plurality of protrusions 60P are formed on the surface 60f of the organic film holding substrate 60. The plurality of protrusions 60P each have a shape corresponding to that of the plurality of depressions 20D shown in FIG. 6. In the case of this embodiment, the plurality of protrusions 60P each have a conical shape. The plurality of organic films 20F are formed on the surface 60f having the plurality of protrusions 60P. Therefore, in the surface 20Ff of the organic film 20F facing the surface 60f, the depressions 20D (see FIG. 6) are formed so as to follow the shape of the protrusions 60P.

In this step, first, the transfer substrate TS1 and the organic film holding substrate 60 are aligned such that the surface 20Bf of the main body portion 20B and the surface 20Fb of the organic film 20F face each other. Next, the transfer substrate TS1 and the organic film holding substrate 60 are brought close together, and the surface 20Bf of the main body portion 20B and the surface 20Fb of the organic film 20F are bonded together as shown in FIG. 11. The organic film 20F is made of, for example, a polyimide resin, and at least the surface 20Fb has adhesiveness.

Next, in the organic film holding substrate separating step included in the LED element preparing step shown in FIG. 8, laser light 61 is irradiated from the side of the organic film holding substrate 60 as shown in FIG. 12, whereby the bonding interface between the surface 60f of the organic film holding substrate 60 and the surface 20Ff of the organic film 20F is peeled off to separate each of the plurality of organic films 20F and the organic film holding substrate 60. FIG. 12 is a cross-sectional view showing the organic film holding substrate separating step shown in FIG. 8.

The laser light 61 is emitted from a laser light source 62. When the organic film 20F is irradiated with the laser light 61, the organic film 20F is rapidly heated and expands, and the interface between the surface 60f of the organic film holding substrate 60 and the surface 20Ff of the organic film 20F is peeled off. By continuously moving the laser light source 62 while irradiating the laser light 61 as schematically indicated by an arrow in FIG. 12, the temperature of the organic film 20F can be lowered before the effect of thermal expansion of the organic film 20F affects the bonding interface between the main body portion 20B and the organic film 20F. When the temperature of the organic film 20F falls, the organic film 20F contracts and the surface 20Ff described with reference to FIG. 6 is exposed.

Note that this embodiment shows the method in which the interface between the surface 60f of the organic film holding substrate 60 and the surface 20Ff of the organic film 20F is peeled off in the state where the plurality of main body portions 20B are held on the transfer substrate TS1. However, as a modification, the holding layer HL1 formed on the transfer substrate TS1 and the main body portion 20B may be separated before this step. In this case, in this step, the main body portion 20B and the organic film 20F are transferred to a transfer substrate different from the transfer substrate TS1 shown in FIG. 11.

Through the above steps, the LED element preparing step shown in FIG. 8 is completed. Namely, as described with reference to FIG. 5, the LED element 20 including the anode electrode 20EA, the cathode electrode 20EC, the main body portion 20B, and the organic film 20F is obtained.

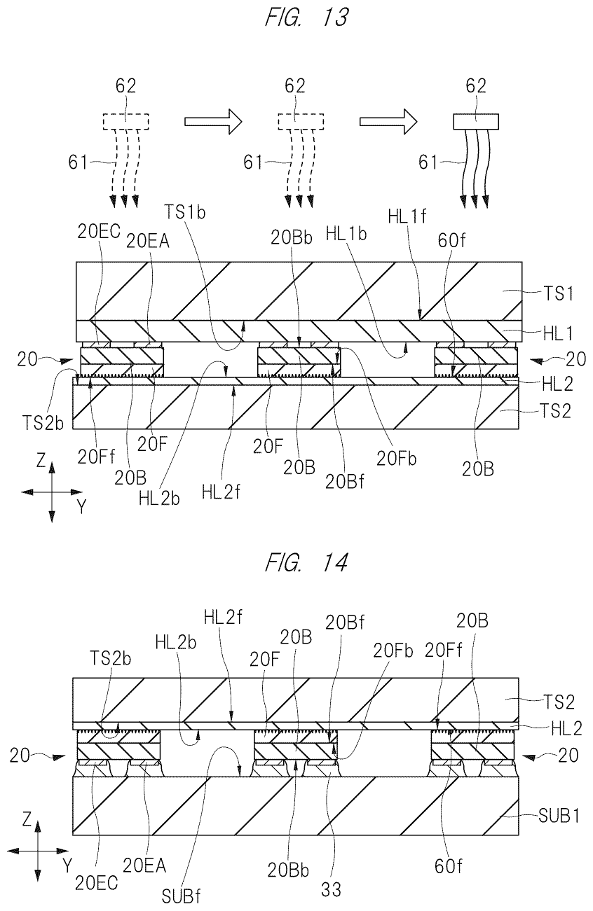

Next, in the LED element holding step shown in FIG. 8, each of the plurality of LED elements 20 held on the transfer substrate TS1 via the holding layer HL1 is transferred to a transfer substrate TS2 as shown in FIG. 13. FIG. 13 is a cross-sectional view showing the LED element holding step shown in FIG. 8.

The transfer substrate TS2 shown in FIG. 13 is, for example, a glass substrate made of glass. The transfer substrate TS2 has a surface TS2b. A holding layer HL2 is formed on the surface TS2b of the transfer substrate TS2. The holding layer HL2 is made of, for example, an elastically deformable organic film, and is formed so as to cover the entire surface TS2b of the transfer substrate TS2. The holding layer HL2 has a surface HL2f facing the surface TS2b of the transfer substrate TS2 and a surface HL2b on the side opposite to the surface HL2f. At least the surface HL2b or the entire holding layer HL2 is made of an adhesive material, and is capable of adhesively holding the main body portion 20B.

However, the adhesive holding strength of the surface HL2b is smaller than the bonding strength of the bonding interface between the surface 20Bf of the main body portion 20B and the surface 20Fb of the organic film 20F. This is to prevent the bonding interface between the surface 20Bf of the main body portion 20B and the surface 20Fb of the organic film 20F from being peeled off in the LED element transferring step to be described later.

In this step, the contact interface between the surface HL1b of the holding layer HL1 and the LED element 20 (specifically, the anode electrode 20EA and the cathode electrode 20EC) is peeled off. As a method for peeling off the contact interface, FIG. 13 illustrates the method of irradiating the laser light 61. In this step, the operation of the laser light source 62 is different from the organic film holding substrate separating step described with reference to FIG. 12. Namely, in this step, the contact interface between the surface HL1b of the holding layer HL1 and the LED element 20 is peeled off by intermittently moving the laser light source 62 as shown in FIG. 13. Furthermore, the irradiation of the laser light 61 is stopped while the laser light source 62 is moving.

The holding layer HL1 is formed so as to cover the entire surface TS1b of the transfer substrate TS1. Therefore, even if a part of the contact interface between the surface TS1b and the surface HL1f is peeled off due to irradiation of the laser light 61 in this step, it is possible to prevent the holding layer HL1 from being entirely peeled off because the other parts are still bonded.

In the example shown in FIG. 13, the method of irradiating the laser light 61 has been described as a method of transferring the LED elements 20 from the transfer substrate TS1 to the transfer substrate TS2. However, as the method of transferring the LED elements 20 from the transfer substrate TS1 to the transfer substrate TS2, for example, a method using the difference in bonding strength between the holding layer HL2 and the holding layer HL1 can be applied. Namely, in the example shown in FIG. 13, the bonding strength of the holding layer HL2 is made larger than the bonding strength of the holding layer HL1. In this case, if the transfer substrate TS1 and the transfer substrate TS2 are separated without irradiation of the laser light 61, the holding layer HL1, which has a relatively low bonding strength, will be peeled off from the LED element 20. In this case, the bonding strength between the main body portion 20B and the organic film 20F needs to be larger than at least the bonding strength between the holding layer HL1 and the LED element 20.

Next, in the LED element transferring step shown in FIG. 8, each of the plurality of LED elements 20 held on the transfer substrate TS2 via the holding layer HL2 is transferred to the substrate SUB1 as shown in FIG. 14. FIG. 14 is a cross-sectional view showing the LED element transferring step shown in FIG. 8.

In this step, after bonding the anode electrode 20EA and the cathode electrode 20EC of each of the plurality of LED elements 20 and the bump electrodes 33 formed on the substrate SUB1, the bonding interface between the surface HL2b of the holding layer HL2 and the surface 20Ff of the organic film 20F is peeled off. The bonding strength of the bonding interface between the surface HL2b of the holding layer HL2 and the surface 20Ff of the organic film 20F is smaller than the bonding strength between the anode electrode 20EA and the cathode electrode 20EC and the bump electrodes 33. Further, as described above, the adhesive holding strength (in other words, bonding strength) of the surface HL2b is smaller than the bonding strength of the bonding interface between the surface 20Bf of the main body portion 20B and the surface 20Fb of the organic film 20F. Therefore, by separating the transfer substrate TS2 after bonding the bump electrodes 33 to the electrodes, the bonding interface between the surface HL2b of the holding layer HL2 and the surface 20Ff of the organic film 20F can be peeled off.

Through the above steps, the display device DSP1 shown in FIG. 1 to FIG. 4 is acquired.

Although the embodiment and typical modifications have been described above, the above-described technique can be applied to various modifications other than the illustrated modifications. For example, the above-described modifications may be combined with each other.

A person having ordinary skill in the art can make various alterations and corrections within a range of the idea of the present invention, and it is interpreted that the alterations and corrections also belong to the scope of the present invention. For example, the embodiment obtained by performing addition or elimination of components or design change or the embodiment obtained by performing addition or reduction of process or condition change to the embodiment described above by a person having an ordinary skill in the art is also included in the scope of the present invention as long as it includes the gist of the present invention.

The present invention can be applied to display devices and electronic devices incorporating display devices.

What is claimed is:

1. A display device comprising:
a first substrate having a first surface; and
a plurality of inorganic light emitting diode elements mounted on the first surface of the first substrate,
wherein each of the plurality of inorganic light emitting diode elements includes:
a main body portion having a second surface facing the first surface of the first substrate and a third surface on a side opposite to the second surface;
a first electrode and a second electrode provided on the second surface of the main body portion; and
a first organic film bonded to the third surface of the main body portion,
wherein the first organic film has a fourth surface bonded to the third surface and a fifth surface on a side opposite to the fourth surface, and
wherein the fifth surface of the first organic film has a plurality of depressions.

2. The display device according to claim 1,
wherein each of the plurality of depressions has a conical shape.

3. The display device according to claim 2,
wherein the first organic film is made of a polyimide resin.

4. The display device according to claim 3,
wherein an area of the fourth surface of the first organic film is equal to or larger than an area of the third surface, and
wherein the entire third surface of the main body portion is bonded to the fourth surface of the first organic film.

5. The display device according to claim 3,
wherein an area of the fourth surface of the first organic film is equal to an area of the third surface.

6. The display device according to claim 3,
wherein a flatness of the fifth surface is lower than a flatness of the third surface.

7. A method of manufacturing a display device comprising steps of:
(a) preparing a first substrate having a first surface;
(b) preparing a plurality of inorganic light emitting diode elements; and
(c) mounting the plurality of inorganic light emitting diode elements on the first surface of the first substrate,
wherein the step (b) includes steps of:
(b1) forming a main body portion, a first electrode, and a second electrode of each of the plurality of inorganic light emitting diode elements on an element forming substrate;
(b2) transferring the plurality of main body portions formed on the element forming substrate to a first transfer substrate;
(b3) bonding the plurality of main body portions and a plurality of first organic films held on an organic film holding substrate, respectively; and
(b4) peeling off a bonding interface between the organic film holding substrate and the plurality of first organic films,
wherein the main body portion has a second surface facing the first surface of the first substrate in the step (c) and a third surface on a side opposite to the second surface,
wherein each of the first electrode and the second electrode is formed on the second surface of the main body portion in the step (b1),
wherein the first organic film has a fourth surface bonded to the third surface in the step (b3) and a fifth surface on a side opposite to the fourth surface, and
wherein the fifth surface of the first organic film has a plurality of depressions.

8. The method of manufacturing the display device according to claim 7,
wherein each of the plurality of depressions has a conical shape.

9. The method of manufacturing the display device according to claim 8,
wherein the first organic film is made of a polyimide resin.
